(19) United States
(12) Patent Application Publication
(10) Pub. No.: US 2012/0260851 A1
(43) Pub. Date: Oct. 18, 2012

(54) METHOD OF MANUFACTURING TRANSPARENT OXIDE THIN FILM

(75) Inventors: YoungZo Yoo, ChungCheongNam-Do (KR); SeoHyun Kim, ChungCheongNam-Do (KR); JeongWoo Park, ChungCheongNam-Do (KR); Taejung Park, ChungCheongNam-Do (KR); Gun Sang Yoon, ChungCheongNam-Do (KR)

(73) Assignee: SAMSUNG CORNING PRECISION MATERIALS CO., LTD., Gyeongsangbuk-do (KR)

(21) Appl. No.: 13/448,614

(22) Filed: Apr. 17, 2012

(30) Foreign Application Priority Data
Apr. 18, 2011 (KR) 10-2011-0035793

(51) Int. Cl. B05D 5/12; C23C 14/34; B05D 3/02; C30B 23/02

(52) U.S. Cl. 117/108; 427/58; 204/192.29; 427/126.3; 427/123; 427/74; 427/66

(57) ABSTRACT

A method of manufacturing a zinc oxide-based thin film for a transparent electrode and a zinc oxide-based thin film manufactured using the method, in which both conductivity and transmittance can be improved. The method includes the step of forming a transparent oxide thin film doped with a dopant on a transparent substrate, and the step of rapidly heat-treating the transparent oxide thin film.

### CROSS REFERENCE TO RELATED APPLICATION

The present application claims priority from Korean Patent Application Number 10-2011-0035793 filed on Apr. 18, 2011, the entire contents of which application are incorporated herein for all purposes by this reference.

### BACKGROUND OF THE INVENTION

1. Field of the Invention

The present invention relates to a method of manufacturing a transparent oxide thin film, for example, a transparent zinc oxide (ZnO)-based thin film, and more particularly, to a method of manufacturing a transparent oxide thin film, is used in photovoltaic cells and organic light emitting diodes (OLEDs).

2. Description of Related Art

Transparent oxide thin films are used in a variety of fields. For example, they are used as a transparent conductive oxide (TCO) thin film in photovoltaic cells, and as a TCO thin film or a light extraction layer material in OLEDs.

In a photovoltaic cell, a TCO thin film forms a transparent electrode that is intended to effectively collect current generated inside the photovoltaic cell, and is required to exhibit high-transmittance characteristic. For use in the photovoltaic cell, the TCO thin film is required to exhibit a high-conductivity characteristic, and is also required to have high haze or the like in order to achieve a light-trapping effect, which leads to an increase in the amount of current collected from a given amount of light.

The TCO thin film is generally made of tin oxide (SnO₂), zinc oxide (ZnO), or indium tin oxide (ITO).

In most cases, the TCO thin film is SnO₂, which is easy to manufacture and has excellent price competitiveness. Recently, however, the development of ZnO, which has high electrical conductivity and high transmittance, is actively underway.

ZnO is an environment-friendly material, with the electrical conductivity thereof being adjustable by the addition of impurities. Other advantages of ZnO are that the provision of raw materials is relatively easy, the cost of production is low, and the thermal stability thereof is excellent. In addition, ZnO forms a suitable transparent electrode for photovoltaic cells, since it exhibits excellent ability to withstand a hydrogen plasma atmosphere, can undergo low-temperature processing, and has a high deposition rate.

However, the specific resistance of the ZnO thin film is higher than that of the ITO thin film, and it is therefore required that the specific resistance of the ZnO thin film be reduced to 10⁻⁴ Ωcm or less by doping it. Available dopants include Group III elements, such as boron (B), aluminum (Al), gallium (Ga) and Indium (In).

However, when the amount of a dopant is increased, transmittance tends to decrease, despite the improvement in conductivity. On the other hand, when the amount of the dopant is decreased, conductivity decreases, despite the increase in transmittance. In particular, because of the phenomenon in which transmittance in a long-wavelength band rapidly decreases with increasing amounts of the dopant, the usage of ZnO as a TCO thin film for a tandem thin film photovoltaic cell (see FIG. 9) is decreasing.

OLEDs are rapidly developing into the stage of commercial distribution, despite their relatively short history. While OLEDs have been mainly developed for display applications, recently, interest in the use of OLEDs for illumination is increasing.

However, OLEDs can extract only about 20% of the light that is generated therein to the outside, whereas about 80% of the light is lost. Due to the low light extraction efficiency, the external light efficiency of OLEDs remains at a low level. Recently, there is increasing interest in the development of light extraction technology as a key technology that can increase the efficiency, luminance and longevity of OLEDs.

A back-side emitting OLED has a basic structure that includes a substrate, a positive electrode layer, an organic layer and a negative electrode layer. A light extraction layer is provided on the front and/or rear surface of the substrate, which generates light, in order to increase light extraction efficiency (see FIG. 10). The light extraction layer is required to exhibit both high transmittance and high light extraction characteristics.

In addition, the positive pole layer, which allows light to pass through, is made of TCO. The positive pole layer is required to exhibit both high transmittance and high conductivity characteristics.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of manufacturing a transparent oxide thin film that has excellent transmittance. Also provided is a method of manufacturing a transparent conductive oxide (TCO) thin film that has excellent conductivity.

In an aspect of the present invention, provided is a method of manufacturing a transparent oxide thin film. The method includes the steps of: forming a transparent oxide thin film doped with a dopant on a transparent substrate, and rapidly heat-treating the transparent oxide thin film.

In an exemplary embodiment, the transparent oxide thin film may be formed by one selected from the group consisting of pulse laser deposition, sputtering, spray coating, chemical vapor (CVD) deposition, evaporation, and molecular beam epitaxy.

In an exemplary embodiment, the dopant may be gallium (Ga).

Here, the dopant may be added in an amount of 2 mol %-8 mol %.

In an exemplary embodiment, the step of rapidly heat-treating the transparent oxide thin film may be carried out via rapid thermal annealing (RTA).

In addition, the step of rapidly heat-treating the transparent oxide thin film may be carried out in a nitrogen atmosphere.

Furthermore, the step of rapidly heat-treating the transparent oxide thin film may be carried out at a temperature ranging from 200° C. to 600° C. for a period ranging from 10 seconds to 10 minutes.

In another aspect of the present invention, provided is a transparent oxide thin film. The transparent oxide thin film is formed on a transparent substrate, is doped with Ga in an amount of 2 mol %-8 mol %, and exhibits a sheet resistance ranging from 9 to 14 ohms per unit area due to rapid heat treatment.

According to embodiments of the invention, it is possible to increase the transmittance and conductivity of the transparent oxide thin film formed on the transparent substrate by rapidly heat-treating it. In particular, it is possible to increase the transmittance in a long-wavelength band.

In addition, according to embodiments of the invention, due to the transmittance and conductivity of the transparent oxide (ZnO) thin film being increased, it is possible to fabricate a photovoltaic cell and an OLED that are highly efficient.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a graph depicting variations in sheet resistance depending on the doping concentration and heat treatment condition of a transparent oxide thin film, which is manufactured according to an embodiment of the invention;

FIG. 2 to FIG. 4 are graphs depicting variations in mobility and carrier concentration depending on the heat treatment condition according to the doping concentration of a transparent oxide thin film, which is manufactured according to an embodiment of the invention;

FIG. 5 to FIG. 8 are graphs depicting variations in transmittance in a long-wavelength band depending on the heat treatment condition of a transparent oxide thin film, which is manufactured according to an embodiment of the invention;

FIG. 9 is a view depicting an example of a photovoltaic cell; and

FIG. 10 is a view depicting an example of an OLED.

### DETAILED DESCRIPTION OF THE INVENTION

Hereinafter, the method of manufacturing the transparent oxide thin film of the invention will be described more fully with reference to the accompanying drawings, in which exemplary embodiments thereof are shown.

In the following description of the present invention, detailed descriptions of known functions and components incorporated herein will be omitted when they may make the subject matter of the present invention unclear.

The method of manufacturing a transparent oxide thin film according to an exemplary embodiment of the invention may be used, for example, for manufacturing a transparent conductive oxide (TCO) thin film, which is used for a transparent electrode of a photovoltaic cell, or a TCO thin film, which is used for a transparent electrode of an organic light emitting diode (OLED).

The method of manufacturing a transparent oxide thin film according to an exemplary embodiment of the invention includes the step of forming a transparent oxide thin film and the step of performing rapid heat treatment.

First, the step of forming a transparent oxide thin film is the step of forming the transparent oxide thin film on a transparent substrate. Here, the term, “transparent” means that transmittance of visible light is preferably 70% or more. In this step, the transparent oxide thin film is formed on the transparent substrate by one selected from among, but not limited to, pulse laser deposition, sputtering, spray coating, chemical vapor deposition (CVD) coating, evaporation, and molecular beam epitaxy.

The transparent oxide thin film may be doped with a dopant. Specifically, a zinc oxide (ZnO)-based transparent oxide thin film may be doped with gallium (Ga). Here, it is preferred that Ga be added in an amount of 2 mol %-8 mol %. The Ga dopant may be added into the transparent oxide before or after the thin film is formed depending on the doping method.

The transparent substrate may be selected from any transparent glass substrates, as long as they have excellent light transmittance and excellent mechanical properties. For example, the transparent substrate can be made of a polymeric material, such as a thermally curable organic film or an ultraviolet (UV)-curable organic film, or chemically tempered glass, such as sodalime (SiO₂—CaO—Na₂O) glass or aluminosilicate (SiO₂—Al₂O₃—Na₂O) glass. The amounts of Na and Fe may be adjusted depending on the application.

The next step of rapid heat treatment is the step of heat-treating the transparent oxide thin film. Thanks to the heat treatment, the crystal structure of the transparent oxide thin film, which is formed on the transparent substrate by the step of forming the transparent oxide thin film, may be stabilized, and its sheet resistance may be reduced. Here, the rapid heat treatment on the transparent oxide thin film may be continuously carried out using vacuum deposition equipment, with which the step of forming the transparent oxide thin film is carried out. This consequently makes it possible to prevent external impurities from becoming attached and sticking to the transparent oxide thin film during processing. It is preferred that the inside of the vacuum deposition equipment be substituted into a nitrogen (N₂) atmosphere during the rapid heat treatment in order to stabilize the reaction.

Since the transparent oxide thin film is formed on the transparent substrate, the transparent substrate is also subjected to heat during the rapid heat treatment on the transparent oxide thin film. In this case, the transparent substrate may be thermally damaged. In order to prevent this problem, the rapid heat treatment is carried out in the form of rapid thermal annealing (RTA). Here, the RTA is a type of heat treatment in which a sample is heat-treated at a rapid heating rate for a short time period.

In the step of rapid heat treatment that is carried out via RTA, it is preferred that a halogen lamp or an infrared (IR) lamp be positioned above the transparent oxide thin film such that heat is not directly applied to the transparent substrate, but is applied only to the transparent oxide thin film.

Here, it is preferred that the rapid heat treatment on the transparent oxide thin film be carried out at a temperature ranging from 200° C. to 600° C. for a period ranging from 10 seconds to 10 minutes in order to reduce the sheet resistance of the transparent oxide thin film and minimize the amount of heat that is applied to the transparent substrate.

When the above-described rapid heat treatment on the transparent oxide thin film is finished, the transparent oxide thin film according to an embodiment of the invention is manufactured. The transparent oxide thin film, which is manufactured by the above-described process, is formed on the transparent substrate. The transparent oxide thin film is doped with Ga an amount of 2 mol %˜8 mol %. In addition, the transparent oxide thin film exhibits a low sheet resistance ranging from 9 to 14 ohms per unit area due to the rapid heat treatment. In other words, the transparent oxide thin film according to an embodiment of the invention can improve both sheet resistance and transmittance, which are in a trade-off relationship with each other, using the doping concentration of Ga and the rapid heat treatment described above. Accordingly, it is possible to manufacture a high-efficiency photovoltaic cell.

### Example

### Manufacture of ZnO-Based Thin Film for Transparent Electrode and Evaluation of Its Characteristics

First, in order to manufacture ZnO-based thin films for a transparent electrode, Ga-doped ZnO-based thin films in which Zinc oxide is doped with Gallium were formed on respective transparent substrates. Here, the three ZnO-based thin films were formed with different doping concentrations of Ga, specifically 4.6 mol %, 5.8 mol %, and 7.8 mol %, in order to determine the optimum doping concentration of Ga.

Afterwards, the respective ZnO-based thin films were subjected to rapid heat treatment. The rapid heat treatment was carried out in the form of RTA in a N₂ atmosphere, and was carried out at a temperature of 500° C. for 1, 2, and 5 minutes, respectively.

The processing temperature was controlled to be 300° C. When thin films were manufactured, the thickness of the ZnO-based thin film doped with 4.6 mol % of Ga was 520 nm, the thickness of the ZnO-based thin film doped with 5.8 mol % of Ga was 490 nm, and the thickness of the ZnO-based thin film doped with 7.8 mol % of Ga was 560 nm.

A description will be given below of the characteristics of the ZnO-based thin films for a transparent electrode, which were manufactured in the Example of the invention, with reference to the figures.

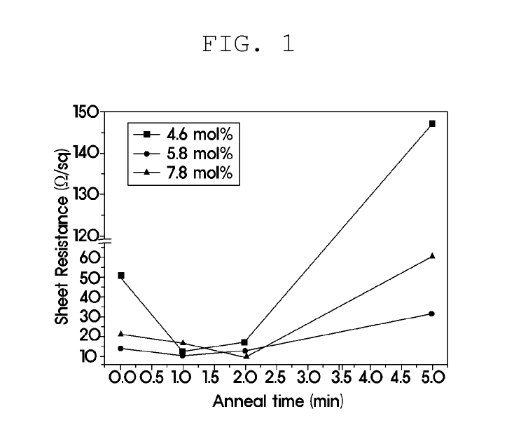

First, FIG. 1 is a graph depicting variations in sheet resistances depending on doping concentration and heat treatment conditions. Referring to FIG. 1, it was observed that the sheet resistances vary depending on the doping concentration of Ga during the heat treatment. When 4.6 mol % of Ga was added, the doping concentration was insufficient, and thus a sufficient amount of carriers was not produced. As a result, a high sheet resistance of 51 ohms per unit area was measured. When 7.8 mol % of Ga was added, some of the added Ga atoms formed defects and acted as a barrier, which interrupted the flow of carriers instead. As a result, a sheet resistance of 16.7 ohms per unit area was measured, which is higher than 11.7 ohms per unit area of 5.8 mol % of Ga.

In addition, after the heat treatment, a decrease in the sheet resistance was observed, irrespective of the doping concentration. This will be described more fully with reference to the concentrations. When 4.6 mol % of Ga was added, after heat treatment for 1 minute, the sheet resistance was measured to be 13.7 ohms per unit area, and it was determined that the sheet resistance rapidly decreased compared to before the heat treatment. The sheet resistance was measured to be 20.7 ohms per unit area after heat treatment for 2 minutes, and to be 148 ohms per unit area after heat treatment for 5 minutes. That is, when Ga was added at a concentration of 4.6 mol %, it was observed that the optimum condition for heat treatment was 1 minute or less. When 5.8 mol % of Ga was added, after heat treatment for 1 minute, the sheet resistance was measured to be 9.8 ohms per unit area, and it was determined that the sheet resistance was decreased in a narrow range compared to before the heat treatment. The sheet resistance was measured to be 16.4 ohms per unit area after heat treatment for 2 minutes, and to be 32 ohms per unit area after heat treatment for 5 minutes. Thus, it was determined that, after heat treatment for 1 minute or more, the sheet resistance tended to increase compared to before the heat treatment. Accordingly, when 5.8 mol % of Ga was added, the optimum heat treatment condition was determined to be 1 minute or less. When 7.8 mol % of Ga was added, after heat treatment for 1 minute, the sheet was measured to be 12.1 ohms per unit area, and it was determined that the sheet resistance was decreased in a narrow range compared to before the heat treatment. The sheet resistance was measured to be 9.1 ohms per unit area after heat treatment for 2 minutes, and to be 62 ohms per unit area after heat treatment for 5 minutes. That is, when Ga was added at a concentration of 7.8 mol %, it was observed that the optimum condition for heat treatment was 2 minutes or less. Due to these results, it was determined that the optimum sheet resistance could be obtained by substantially increasing the heat treatment time in response to the increase in the doping concentration. This is because the activation energy is required to increase with increasing amounts of the dopant.

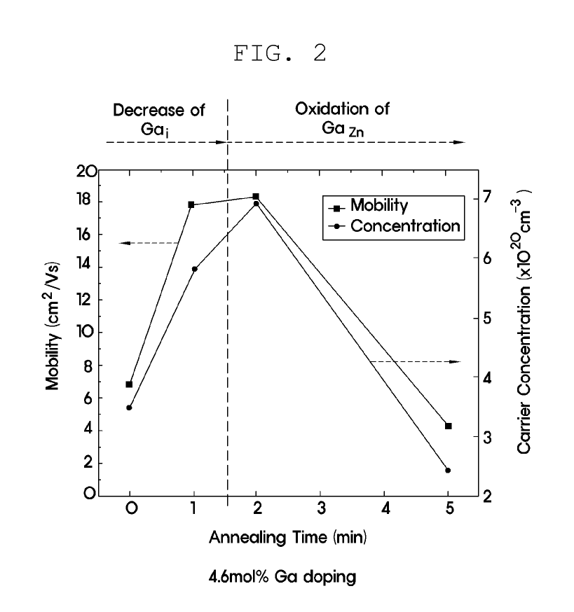

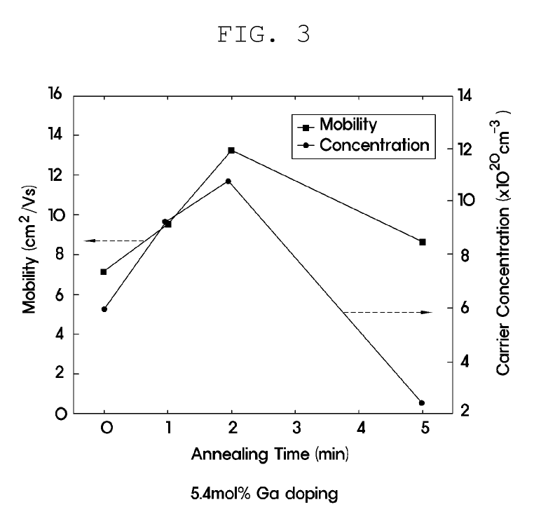

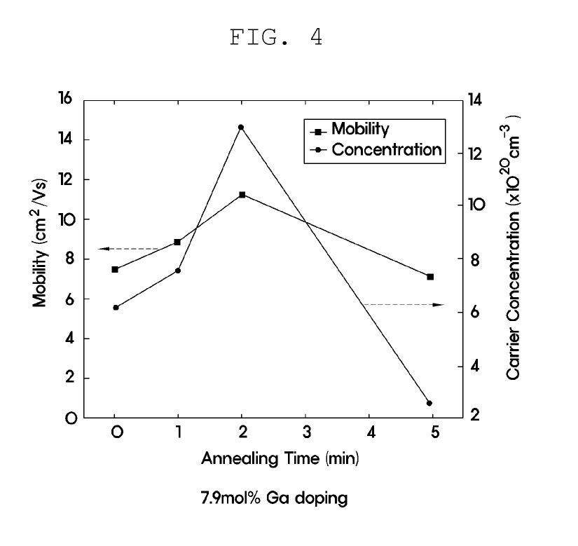

In addition, FIG. 2 to FIG. 4 are graphs depicting variations in mobility and carrier concentration depending on the heat treatment condition according to doping concentration. Referring to FIG. 2 to FIG. 4, it was determined that the variation in mobility depending on the heat treatment time was not relatively significant. That is, the decrease in sheet resistance due to heat treatment depends relatively on the variation in carrier concentration. This is because, when a Ga-doped ZnO-based thin film is formed, Ga atoms, which occupy oxygen vacancies and interstitial sites in the crystal structure of ZnO, are activated due to heat treatment, so that the concentration of extrinsic donors due to Ga increases.

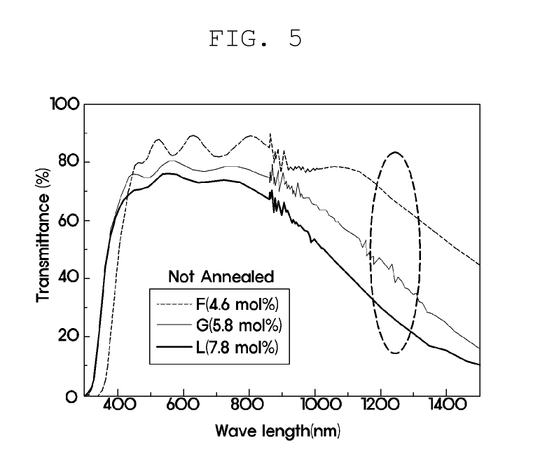

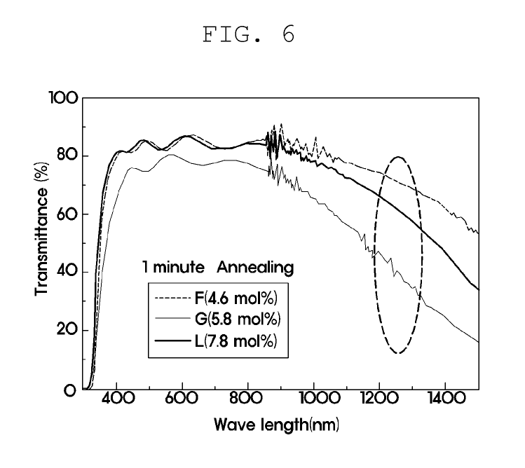

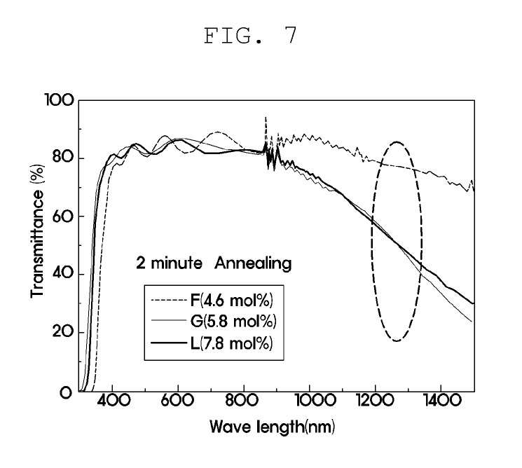

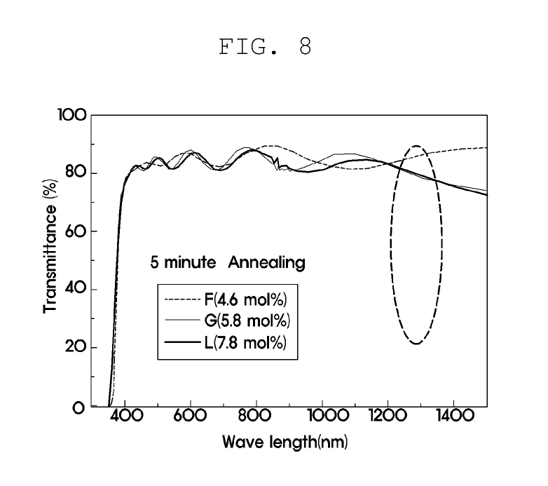

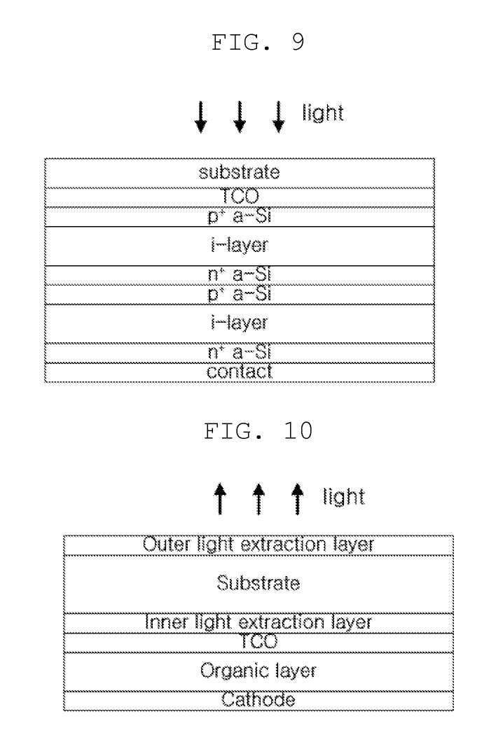

FIG. 5 to FIG. 8 are graphs depicting variations in transmittance in a long-wavelength band depending on the heat treatment condition. Referring to FIG. 5 to FIG. 8, it was observed that the transmittance of ZnO-based thin films in a long-wavelength band increased with heat treatment time increasing. The transmittance in the long-wavelength band was increased by the heat treatment because of the following: In the manufacture of a Ga-doped ZnO-based thin film, dopant atoms at interstitial sites in the crystal structure of ZnO, were activated by the heat treatment, so that the concentration of extrinsic donors due to the dopant was increased, whereas the dopant atoms at the interstitial sites, which contribute to free carrier absorption, decreased. It was observed that the transmittance of light in the long-wavelength band, which is absorbed by free charges, was increased accordingly. Here, FIG. 5 to FIG. 8 show that the transmittance increases with decreasing concentrations of the Ga dopant, and that the transmittance in the long-wavelength band is increased within the shortest time by the heat treatment with the decreasing concentrations of the Ga dopant.

As set forth above, the method of manufacturing a transparent oxide thin film according to an exemplary embodiment of the invention can be used in the manufacture of a transparent oxide thin film, which is used, for example, as a transparent light extraction layer of an OLED.

Here, the oxide thin film may be one or a combination of at least two selected from a group of materials consisting of ZnO, TiO₂, SnO₂, SrTiO₃, VO₂, V₂O₃, SrRuO₃ and SiO₂.

The dopant of the oxide thin film may be one or a combination of at least two selected from a group of metals consisting of Mg, Cd, S, Ga, Al, F, Mn, Co, Cu, Nb, Nd, Sr, W and Fe.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of manufacturing a transparent oxide thin film, comprising:
forming a transparent oxide thin film on a transparent substrate; and
rapidly heat-treating the transparent oxide thin film.

2. The method of claim 1, wherein the transparent oxide thin film is formed by one selected from the group consisting of pulse laser deposition, sputtering, spray coating, chemical vapor deposition, evaporation, and molecular beam epitaxy.

3. The method of claim 1, wherein the transparent oxide thin film comprises a zinc oxide-based thin film which comprises zinc oxide doped with gallium.

4. The method of claim 3, wherein the gallium is added in an amount of 2 mol %˜8 mol %.

5. The method of claim 1, wherein the transparent oxide thin film comprises at least one selected from the group consisting of ZnO, TiO₂, SnO₂, SrTiO₃, VO₂, V₂O₃, SrRuO₃ and SiO₂.

6. The method of claim 1, wherein the transparent oxide thin film is doped with a dopant.

7. The method of claim 6, wherein the dopant comprises at least one selected from the group consisting of Mg, Cd, S, Ga, Al, F, Mn, Co, Cu, Nb, Nd, Sr, W and Fe.

8. The method of claim 1, wherein the rapidly heat-treating the transparent oxide thin film comprises rapid thermal annealing.

9. The method of claim 8, wherein the rapidly heat-treating the transparent oxide thin film is carried out in a nitrogen atmosphere.

10. The method of claim 8, wherein the rapidly heat-treating the transparent oxide thin film is carried out at a temperature ranging from 200° C. to 600° C. for a time period ranging from 10 seconds to 10 minutes.

11. The method of claim 1, wherein
the transparent substrate comprises a substrate of a photovoltaic cell, and
the transparent oxide thin film comprises an electrode layer.

12. The method of claim 1, wherein
the transparent substrate comprises a substrate of an organic light emitting diode, and
the transparent oxide thin film comprises an electrode layer.

13. The method of claim 1, wherein
the transparent substrate comprises a substrate of an organic light emitting diode, and
the transparent oxide thin film comprises a light extraction layer.
